(19) United States
(12) Patent Application Publication
(10) Pub. No.: US 2005/0276027 A1
(43) Pub. Date: Dec. 15, 2005

(54) Electronic device for shielding EMI

(75) Inventors: Ling-Ling Shen, Shen-Zhen (CN); Yu-Xiang Wang, Shen-Zhen (CN); Hui Chen, Shen-Zhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/142,529

(22) Filed: Jun. 1, 2005

(30) Foreign Application Priority Data
Jun. 12, 2004 (CN) 200410027692.5

(51) Int. Cl. H05K 9/00

(52) U.S. Cl. 361/753; 361/816; 361/818

(57) ABSTRACT

A electronic device for shielding electromagnetic interference (EMI) including a metal shield, a printed circuit board (PCB) having a ground layer, and a number of ground pads arranged at edges of the PCB and in electrical conductivity with the ground layer. The ground pads lies close to edges of the metal shield. During solder reflowing process, solder is laid on the ground pads, and a height of the solder is adjusted to meet spaces or gaps of the shield. When the PCB is placed into the shield, the solder on the ground pads is in electrical conductivity with the metal shield to eliminate spaces or gaps thereof. So the EMI coupling which causes EMI signals interfering with sensitive components is avoided.

### BACKGROUND OF THE INVENTION

1. Field of the Invention

The present invention relates to an electronic device for shielding electromagnetic interference (EMI), and particularly to an electronic device for shielding EMI by adjusting structure of a printed circuit board (PCB) inside the electronic device.

2. General Background

Electronic circuitry assemblies, printed circuits boards (PCB), and substrates containing circuitry and electronic components mounted thereon, often require electromagnetic interference (EMI) shields to limit the likelihood of signal interferences from electromagnetic waves, such as those caused by radio-frequency (RF) signals.

It is known that the operation and performance of sensitive electronic components, such as integrated circuits (ICs), can be affected by the presence of interfering electromagnetic signals. Certain electronic components and devices are known to emit electromagnetic signals during their operation. In particular, on a circuit board, components emitting EMI signals can detrimentally affect the performance, reliability and even operability of other electronic components on the same board. Three essential elements must be present for an EMI situation to exist, including: an electrical noise (EMI) source, a coupling path, and a victim receptor. The noise source emission can be either a conducted voltage or current, or an electric or magnetic field propagated through space. It is known that certain equipment and systems can serve as both EMI sources and receptors. A coupling path may exist between signal sources and receptors and can be divided into two basic groups: radiation or field coupling by electromagnetic wave propagation through space or materials (hereinafter known as “air coupling”), and coupling via conducted paths through which current can flow (hereinafter known as “board coupling”).

To minimize the presence of interfering signals with sensitive electronic components and the effects of air coupling and board coupling, whether the interfering source is on the same assembly or apart from the receptor device being a sensitive electronic, the use of EMI shielding is often employed. Such as a notebook, which has a plastic enclosure and a PCB therein. Two metal shields are mounted inside the enclosure to shield electromagnetic wave through space. But problems frequently arise due to movement of the shields during securing and also due to gapping along the interface between the shield edge and the PCB. In particular, surfaces of the PCB and shield edges are not uniformly planar and these nonuniformities cause inconsistencies in contacts due to spaces or gaps resulting at interface between the PCB and the mounted shield edge.

A conductive gasket or clip is often mounted at the surfaces of the PCB and shield edges to prevent the electromagnetic wave from crossing the gap. However, it may be needed to open the shields during using the notebook. Continually moving or removing the shields from the PCB will deform the gasket or clip thereon. EMI shielding effect is getting worse.

What is needed is a electronic device for shielding EMI. The EMI shielding effect does not get worse during using the electronic device.

### SUMMARY

A electronic device for shielding electromagnetic interference (EMI) including a metal shield, a printed circuit board (PCB) having a ground layer, and a plurality of ground pads arranged at edges of the PCB and in electrical conductivity with the ground layer. The ground pads lies close to edges of the metal shield. During solder reflowing process, solder is laid on the ground pads, and a height of the solder is adjusted to meet spaces or gaps of the shield. When the PCB is placed into the shield, the solder on the ground pads is in electrical conductivity with the metal shield to eliminate spaces or gaps thereof. So the EMI coupling which causes EMI signals interfering with sensitive components is avoided.

It is of advantage that moving or removing the metal shield from the PCB thereon does not change deform the ground pads and the solder. Shielding effect of the metal shied is sustained.

Other objects, advantages and novel features of the invention will become more apparent from the following detailed description when taken in conjunction with the accompanying drawings, in which:

### BRIEF DESCRIPTION OF THE DRAWINGS

FIG. 1 is a sectional view of a PCB inside an electronic device in accordance with a preferred embodiment of the present invention; and

FIG. 2 is a distributing diagram of ground pads of a PCB in accordance with a preferred embodiment of the present invention.

### DETAILED DESCRIPTION OF THE PREFERRED EMBODIMENT

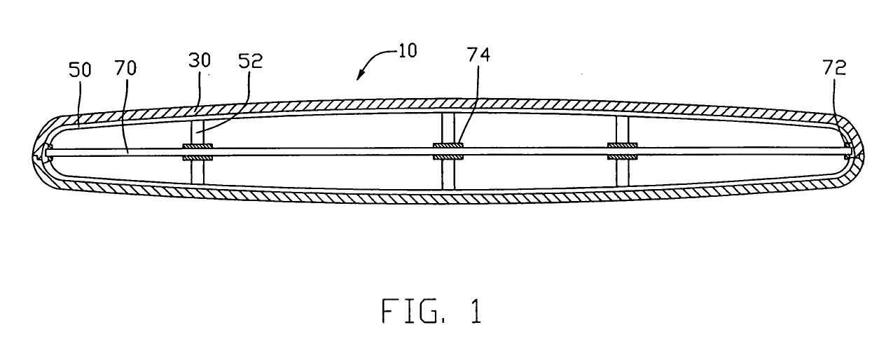

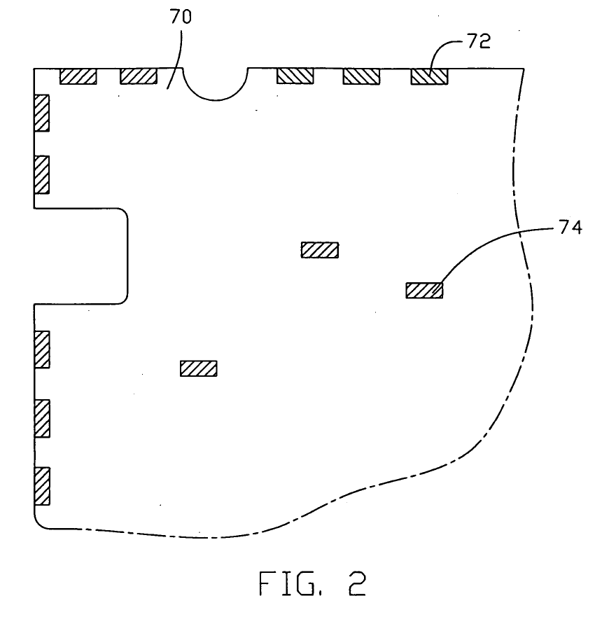

Referring to FIGS. 1 and 2, an electronic device 10 in accordance with a preferred embodiment of the present invention includes an enclosure 30, a metal shield 50, and a PCB 70.

The enclosure 30 is formed with plastic or other materials to decorate the electronic device 10 and to prevent elements inside the electronic device 10 from being damaged. Normally the enclosure 30 does not provide function of preventing EMI.

The metal shield 50 is mounted inside the enclosure 30 and over the PCB 70 to inhibit interference from propagating to a receptor or to prevent EMI signals from being emitted by an emitting source outside the electronic device 10. The metal shield 50 is usually precisely placed on the PCB 70 at a prescribed location and attempts to be grounded, usually with a ground layer of the PCB 70. The metal shield 50 is typically installed by securing the metal shield 50 to the PCB 70. Often, compression fittings or screws are used to secure the metal shield 50 in place.

A plurality of ground pads 72 is set at edges of a top layer and a bottom layer of the PCB 70. The ground pads 72 are in electrical conductivity with a ground layer (not pictured) of the PCB 70. A space between every two neighboring ground pads is equal to or less than a determined interval or value, such as 0.13 mm. During solder reflowing process, solder is laid on the ground pads 72, and a height of the solder is adjusted to meet spaces or gaps of the metal shield 50. When the PCB 70 is placed into the metal shield 50, the solder on the ground pads 72 is in electrical conductivity with the metal shield 50 to eliminate spaces or gaps thereof. So the EMI coupling which causes EMI signals interfering with sensitive components is avoided. Additionally, moving or removing the metal shield 50 from the PCB 70 thereon does not deform the ground pads 72 and the solder. Shielding effect of the metal shied 50 is sustained.

Many electronic elements on the PCB 70 are grounded via the ground layer of PCB 70. So the ground layer of PCB 70 must be in electrical conductivity with the metal shield 50 by using screws to fix the PCB 70 to the metal shield 50. Normally the screws are set at edges of the PCB 70. Because the ground layer of PCB 70 is a whole metal layer that has a resistance. Areas near the screws have lower potential than other areas. Potential unbalance causes current flowing on the ground layer of PCB 70. EMI happens due to the current flowing.

A plurality of ground pads 74 is arranged at the PCB 70 as grounded points. These grounded points even the potential of the ground layer of PCB 70. These grounded points are in electrical conductivity with the metal shield 50 via a plurality of metal protrusions 52 which is formed from the metal shield 50. So the ground pads 74 are corresponding to the metal protrusions 52 one by one.

It is believed that the present embodiment and its advantages will be understood from the foregoing description, and it will be apparent that various changes may be made thereto without departing from the spirit and scope of the invention or sacrificing all of its material advantages, the examples hereinbefore described merely being preferred or exemplary embodiments.

1. An electronic device for shielding electromagnetic interference (EMI) comprising:
a metal shield;
a printed circuit board (PCB) located in the metal shield, and comprising a ground layer; and
a plurality of ground pads arranged at edges of the PCB, and in electrical conductivity with the ground layer, the ground pads lying close to edges of the metal shield.

2. The electronic device as claimed in claim 1, wherein the metal shield comprises a plurality of metal protrusions arranged from an inner surface thereof.

3. The electronic device as claimed in claim 2, wherein a plurality of ground pads is arranged at the PCB respectively corresponding to the metal protrusions.

4. The electronic device as claimed in claim 1, wherein the ground pads are arranged at a top layer and a bottom layer of the PCB.

5. The electronic device as claimed in claim 4, wherein solder lies on the ground pads is adjustable.

6. The electronic device as claimed in claim 1, wherein a space between every two neighboring ground pads is equal to or less than a determined value.

7. The electronic device as claimed in claim 6, wherein the determined value is 0.13 mm.

8. An electromagnetic interference (EMI) shielding method for a printed circuit board (PCB) comprising:
providing a metal shield for inhibiting EMI from propagating to a receptor outside the metal shield or for preventing EMI signals from being emitted by an emitting source outside the metal shield;
arranging a plurality of ground pads at edges of the PCB, the ground pads being in electrical conductivity with the ground layer, the ground pads lying close to edges of the metal shield.

9. The method as claimed in claim 8, wherein the metal shield comprises a plurality of metal protrusions arranged from an inner surface thereof.

10. The method as claimed in claim 9, wherein a plurality of ground pads is arranged at the PCB respectively corresponding to the metal protrusions.

11. The method as claimed in claim 8, wherein the ground pads are arranged at a top layer and a bottom layer of the PCB.

12. The method as claimed in claim 11, further comprising the step of placing solder to the ground pads.

13. The method as claimed in claim 12, wherein the solder lies on the ground pads is adjustable.

14. The method as claimed in claim 8, wherein a space between every two neighboring ground pads is equal to or less than a determined value.

15. The method as claimed in claim 13, wherein the determined value is 0.13 mm.

16. A method for shielding an electronic device from electromagnetic interference (EMI), comprising the steps of:
enclosing said electronic device by an enclosure;
forming a metal shield inside said enclosure to perform EMI shielding;
disposing a printed circuit board (PCB) having a ground layer therein within said enclosure so as to be shielded by said metal shield; and
arranging a plurality of ground pads at edges of said PCB to electrically connect with said ground layer of said PCB and said metal shield.

17. The method as claimed in claim 16, further comprising the step of arranging a plurality of ground pads on said PCB away from said edges of said PCB so as to electrically connect with a plurality of metal protrusions extending from an inner surface of said metal shield.

18. The method as claimed in claim 16, wherein each of said plurality of ground pads at said edges of said PCB is arranged in a predetermined interval along said edges of said PCB.
